(19) United States
(12) Patent Application Publication
(10) Pub. No.: US 2007/0285139 A1
(43) Pub. Date: Dec. 13, 2007

(54) Amplifier Circuit and Method for Correcting the Duty Ratio of a Differential Clock Signal

(75) Inventor: Patrick Heyne, Munich (DE)

Correspondence Address: EDELL, SHAPIRO & FINNAN, LLC, 1901 RESEARCH BLVD., SUITE 400, ROCKVILLE, MD, 20850, US

(73) Assignee: QIMONDA AG, Munich (DE)

(21) Appl. No.: 11/748,703

(22) Filed: May 15, 2007

Related U.S. Application Data
(63) Continuation of application No. PCT/EP05/55691, filed on Nov. 2, 2005.

(30) Foreign Application Priority Data
Nov. 15, 2004 (DE) 102004055036.0

(51) Int. Cl. H03K 3/017

(52) U.S. Cl. 327/175

(57) ABSTRACT

An amplifier circuit is configured to correct the duty ratio of a differential clock signal to a desired value of 50% via a differential amplifier including a MOS transistor pair. The clock signal to be corrected is applied to a respective gate terminal of the MOS transistor pair of the amplifier circuit, a differential analog duty ratio correction signal is generated by in each case integrating the true and complementary clock signal delivered by each MOS transistor at a source/drain terminal. The differential duty ratio correction signal is in each case applied to the electrically separated substrate terminals of the MOS transistor pair so that the substrate voltages, and thus the turn-on voltages of the MOS transistors of the transistor pair are in each case conversely influenced.

### CROSS REFERENCE TO RELATED APPLICATIONS

This application is a continuation of International Application No. PCT/EP2005/055691, filed on Nov. 2, 2005, entitled “Amplifier Circuit and Method for Correcting the Duty Ratio of a Differential Clock Signal,” which claims priority under 35 U.S.C. §119 to Application No. DE 102004055036.0 filed on Nov. 15, 2004, entitled “Amplifier Circuit and Method for Correcting the Duty Ratio of a Differential Clock Signal,” the entire contents of which are hereby incorporated by reference.

### BACKGROUND

With synchronous high-performance data transmissions with two data bits per clock cycle, e.g., in systems with DDR memory chips, it is of great importance to achieve a maximum data eye width. Deviations in the duty ratio of the clock signal will always generate a longer data bit which is followed by a shorter one since the data are transmitted synchronously with the clock signal. This shorter data bit restricts the upper cut-off frequency of the system or chip. Referred to the memory chip, this means a lower yield of the high speed class.

In principle, there are two known methods for correcting duty ratio of symmetric clock signals:
Digital solutions with chains of delay circuits in which rising and falling edges are discretely controlled. This enables the data eyes to be controlled. The disadvantages are the reduced accuracy which has an effect particularly at ultra-high frequency clock signals, and the large requirement for chip area of such digital solutions.
Analog solutions with integrators which detect a deviation of the duty ratio from 50% and drive a corrector.

In the case of the analog solutions, two principles have up to this time been known:
The two complementary components of the clock signal are capacitively loaded in order to reduce the edge steepness. The signal components are then added with different voltage offsets. This shifts the points of intersection.
The two complementary clock signals are influenced in such a manner that their rise time and decay time is different.

### SUMMARY

An amplifier circuit is configured to correct the duty ratio of a differential clock signal to a desired value (e.g., 50%) via a differential amplifier including a MOS transistor pair. The clock signal to be corrected is applied to a respective gate terminal of the MOS transistor pair of the amplifier circuit, a differential analog duty ratio correction signal is generated by in each case integrating the true and complementary clock signal delivered by each MOS transistor at a source/drain terminal. The differential duty ratio correction signal is in each case applied to the electrically separated substrate terminals of the MOS transistor pair so that the substrate voltages, and thus the turn-on voltages of the MOS transistors of the transistor pair are in each case conversely influenced.

The above and still further features of the present invention will become apparent upon consideration of the following definitions, descriptions and descriptive figures of specific embodiments thereof, wherein like reference numerals in the various figures are utilized to designate like components. While these descriptions go into specific details of the invention, it should be understood that variations may and do exist and would be apparent to those skilled in the art based on the descriptions herein.

### BRIEF DESCRIPTION OF THE DRAWINGS

The amplifier circuit and method are explained in more detail below with reference to exemplary embodiments, where:

FIG. 1 diagrammatically shows an embodiment of a differential amplifier circuit;

FIG. 2 graphically shows a signal timing diagram of the differential clock signal present as input signal at the differential amplifier circuit according to FIG. 1;

FIG. 3 graphically shows the dependence of the duty ratio (upper curve a) on the change in substrate voltages of the MOS transistor pair T1 and T2 of the amplifier circuit according to FIG. 1;

FIG. 4 graphically shows a signal timing diagram of one of the output signals (ACLt) at two different substrate voltages of the transistor T2 according to FIG. 1;

FIG. 5 graphically shows in each case the dependence of the turn-on voltage, of the drain current and of the source current of a single NMOS transistor (e.g., of the transistor T2 according to FIG. 1 in dependence on the substrate voltage applied to it); and

FIG. 6 diagrammatically shows the block diagram of a control loop containing the correction amplifier circuit and the detector circuit, for the analog correction of the duty ratio of a differential clock signal.

### DETAILED DESCRIPTION

The amplifier circuit described herein offers another analog solution in which the electrical characteristics of a pair of transistors of a differential amplifier (buffer amplifier) are changed and thus the shape of the curve of the output signal of the differential amplifier is changed.

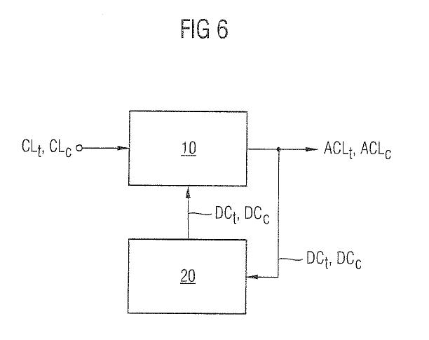

In FIG. 6, a block diagram forming the basis of the present invention and also of the known analog principles of correction is shown in which a differential amplifier 10, used as corrector, receives the differential uncorrected clock signal CLt (true) and CLc (complementary) and delivers at its output the corrected complementary clock signal ACLt (true) and ACLc (complementary). A detector 20 acting as integrator picks up the complementary clock signal ACLt and ACLc at the output of the corrector or differential amplifier 10 and obtains from this a differential correction signal DCt (true) and DCc (complementary) which corresponds to the deviation of the clock signal ACLt and ACLc from the ideal 50% value. The differential correction signal DCt and DCc is applied to the differential amplifier 10 acting as corrector, in such a manner that a positive and negative deviation of the received clock signal CLt and CLc from 50% is in each case compensated.

The amplifier circuit and a method for correcting the duty ratio of a differential clock signal described herein can be integrated more accurately and with the least possible effort into a CMOS process and allows the duty ratio deviations of differential clock signals with higher frequency to be corrected.

This effect is achieved by an amplifier circuit for correcting the duty ratio of a differential clock signal to a desired value of 50%, with a differential amplifier stage of a MOS transistor pair, the gate terminal pair of which receives a clock signal to be corrected and the source/drain terminal pair of which delivers the clock signal with corrected duty ratio, and which has a correction signal input terminal pair which receives an analog duty ratio correction signal generated by a detector stage connected as integrator and connected to the source/drain terminal pair of the differential amplifier stage, wherein the correction signal input terminal pair is formed by the electrically separated substrate terminals of the MOS transistor pair so that the duty ratio correction signal in each case influences the substrate voltages, and thus the respective turn-on voltage of the MOS transistors of the transistor pair in the opposite sense, i.e., conversely influenced.

If a number of such amplifier circuits are used in series, the range of correction can be increased.

If the MOS transistor pair of the differential amplifier stage has two NMOS transistors, as preferred, the current sources in each case connected to the drain terminal of each MOS transistor of the differential amplifier stage can be implemented by p-channel MOS transistors.

A method for correcting the duty ratio of a differential clock signal to a desired value of 50% via a differential amplifier having a MOS transistor pair, includes the following steps:

applying the clock signal to be corrected to a respective gate terminal of the MOS transistor pair; generating a differential analog duty ratio correction signal by in each case integrating the true and complementary clock signal delivered by each MOS transistor of the differential amplifier at its source/drain terminal, and applying the differential duty ratio correction signal thus generated to a correction signal input terminal pair of the differential amplifier, wherein the differential duty ratio correction signal is in each case applied to the electrically separated substrate terminals of the MOS transistor pair which form the correction signal input terminal pair of the differential amplifier so that in each case the substrate voltages, and thus the turn-on voltages of the MOS transistors of the transistor pair are influenced in the opposite sense, i.e., conversely influenced.

With respect to the block diagram shown in FIG. 6, the correction signals DCt and DCc change the substrate voltages of the two MOS transistors of the differential amplifier in accordance with the solutions according to the amplifier circuit previously described. Changing the substrate voltage changes the turn-on voltage of the respective transistor. Thus, this transistor conducts above a different input voltage at the gate or a different current flows at the same input voltage. This allows the discharge current of the signals ACLt, ACLc at the output node to be delayed in time. The differential amplifier stage can thus be operated symmetrically and used as corrector.

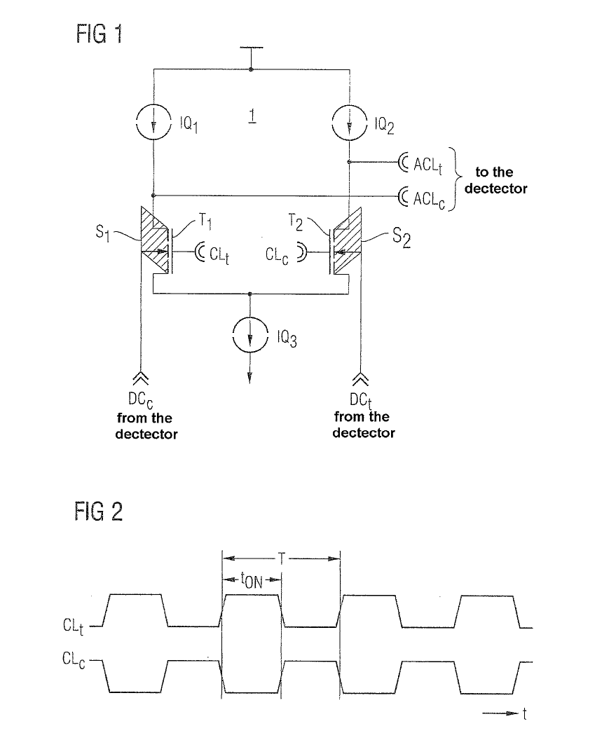

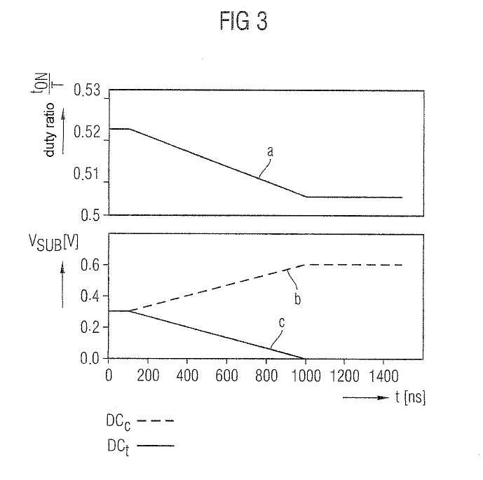

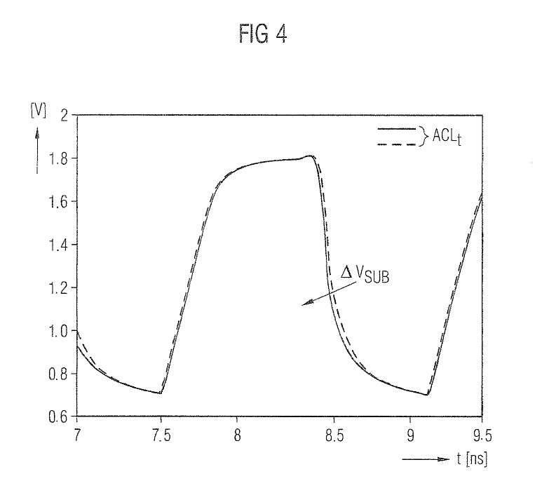

FIG. 1 in a simplified manner shows a diagram of an exemplary embodiment of an amplifier circuit, constructed as differential amplifier stage 1, for correcting the duty ratio of a differential clock signal CLt, CLc shown for example in the signal timing diagram of FIG. 2. The differential amplifier stage 1 shown includes a MOS transistor pair consisting of two NMOS transistors T1, T2, with separate, i.e., electrically isolated, substrate areas S1, S2. The two gate terminals of the NMOS transistors T1 and T2 in each case receive the true clock signal CLt and the complementary clock signal CLc. The terminals of the substrate areas S1 and S2 of the two transistors T1 and T2 in each case receive a complementary correction signal DCc and true correction signal DCt, generated by an integrator detector (FIG. 6: number 20), as analog duty ratio correction signal via which the respective substrate voltage, and thus the respective turn-on voltage of the NMOS transistors T1 and T2 is changed in dependence on the correction signals DCc and DCt, indicating a deviation of the duty ratio from 50%, so that the respective transistor T1, T2 conducts above a different input voltage at the gate terminal or a different current flows at the same input voltage. The corrected complementary and true clock signals ACLc and ACLt are in each case picked up at the drain terminals of the two transistors T1, T2 of the differential amplifier stage 1 and conducted to the detector. It must be noted that the output terminals, i.e., the drain terminals carrying the corrected clock signals ACLt and ACLc, can be loaded in each case with a capacitive load. The differential amplifier stage 1 used as duty ratio correction circuit thus operates asymmetrically which will be explained in greater detail with reference to FIG. 3 in the text which follows. In the drain and source lines of the two NMOS transistors T1 and T2, current sources IQ1, IQ2 and IQ3, shown symbolically, are used via which the differential gain and the operating point of the two NMOS transistors T1 and T2 can be adjusted. These current sources IQ1-IQ3 can be current mirror circuits as are known in the prior art.

FIG. 2 shows merely for example a complementary clock signal which consists of the true clock signal CLt shown in the upper row of FIG. 2 and the complementary clock signal CLc shown in the lower row of FIG. 2. The duty ratio is defined, for example, as the ratio of the turn-on time tₒₙ to the period time T of the clock signal and is 50% (0.5) in the ideal case.

FIG. 3 graphically shows results of a circuit simulation which was based on the differential amplifier circuit according to the embodiment, shown in FIG. 1. In the upper part of FIG. 3, curve a represents the change in duty ratio with time in dependence on the change in substrate voltage V_{SUB} shown in the lower part of FIG. 3, the dashed curve b showing the change with time of the substrate voltage (correction signal DCc) of the transistor T1 and the lower curve c, extending mirror-symmetrically to the curve b, showing the change with time of the substrate voltage (correction signal DCt) of the transistor T2. FIG. 3 shows that the duty ratio is reduced by approx. 2% whereas the correction voltage DCc, supplied to the substrate area S1 of the transistor T1 grows by about 0.3 V according to curve b and the correction voltage DCt, which is supplied to the substrate area S2 of the transistor T2, shown by curve c drops by about 0.3 V.

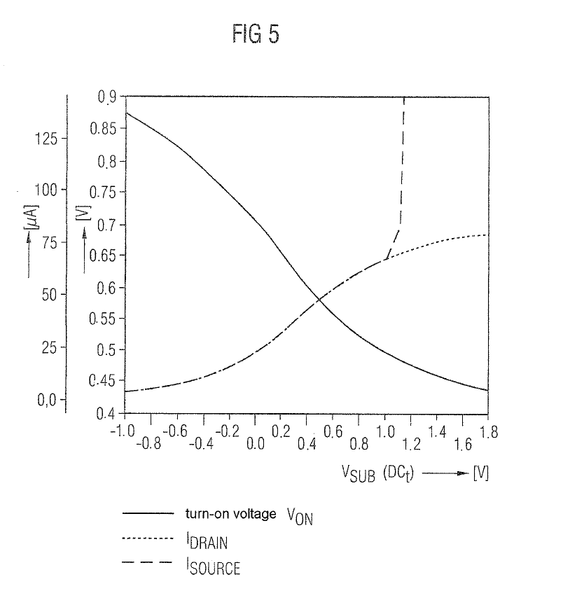

FIG. 4 shows the variation of the (corrected) true clock signal ACLt picked up at the drain terminal of the transistor T2 as simulation result. In comparison with the signal variation drawn dashed, the signal variation drawn continuously shows that the falling edge starts slightly earlier at a reduced value of the substrate voltage V_{SUB} (curve b in FIG. 3).

The diagram of FIG. 5 shows simulated variations in each case of the turn-on voltage Vₒₙ (continuous line), of the drain current I_{DRAIN} (dot-dashed line) and of the source current I_{SOURCE} (dashed line) in dependence on various substrate voltages (e.g., DCt of the transistor T2) from −1.0 V to +1.8 V. It can be seen that the turn-on voltage Vₒₙ becomes less towards higher values of the substrate voltage DCt, that is to say that the transistor conducts at lower voltages at the gate input. However, as show in FIG. 5, the diode junctions of the transistor T2 turn on when the substrate voltages are too high (approx. 1.1 V) and the source current I_{SOURCE} (dashed curve) rises abruptly. With the described amplifier circuit, attention must therefore be paid to the fact that the correction voltages DCc and DCt, delivered by the integrator stage (not shown) acting as detector, which are in each case applied to the substrate areas S1 and S2 of the transistors T1 and T2, do not reach this limit value of approx. 1.1 V.

It must be noted that the range of correction can be increased if a number of such amplifier circuits are used in series. For example, using five differential amplifier stages makes it possible to correct a distortion of approx. 10% if about 2% distortion of the duty ratio can be corrected via one stage.

Previously, an optional exemplary embodiment of an amplifier circuit for correcting the duty ratio of a differential clock signal by using two n-channel MOS transistors has been described with reference to FIGS. 1 to 5. However, the method implemented via such a differential amplifier circuit can also be carried out via a differential amplifier stage implemented with p-channel MOS transistors in which the differential duty ratio correction signal is also in each case applied to the electrically separated (isolated) substrate terminals of the MOS transistor pair so that the substrate voltages, and thus the turn-on voltages of the MOS transistors of the transistor pair are influenced separately in the opposite sense.

While the invention has been described in detail with reference to specific embodiments thereof, it will be apparent to one of ordinary skill in the art that various changes and modifications can be made therein without departing from the spirit and scope thereof. Accordingly, it is intended that the present invention covers the modifications and variations of this invention provided they come within the scope of the appended claims and their equivalents.

What is claimed is:

1. An amplifier circuit to correct the duty ratio of a differential clock signal to a desired value, the amplifier circuit comprising:
a differential amplifier stage with a MOS transistor pair including:
a gate terminal pair configured to receive a clock signal to be corrected;
a source/drain terminal pair configured to deliver a corrected clock signal with corrected duty ratio; and
a correction signal input terminal pair configured to receive an analog duty ratio correction signal; and
a detector stage connected as an integrator to the correction signal input terminal pair of the differential amplifier stage and configured to generate the analog duty ratio correction signal;
wherein the correction signal input terminal pair comprises electrically separated substrate terminals of the MOS transistor pair such that receipt of the duty ratio correction signal influences substrate voltages of the MOS transistor pair, thereby conversely influencing a respective turn-on voltage of the MOS transistor pair.

2. The amplifier circuit according to claim 1, wherein the corrected clock signal has a corrected duty ratio of 50%.

3. The amplifier circuit according to claim 1, wherein the MOS transistor pair includes two NMOS transistors.

4. The amplifier circuit according to claim 1, wherein the source/drain terminals of the two MOS transistors are also connected to a current source.

5. The amplifier circuit according to claim 1, further comprising:
at least one further differential amplifier stage connected in series to the first differential amplifier stage, wherein a range of correction of the duty ratio of the differential clock signal is increased.

6. A method for correcting the duty ratio of a differential clock signal to a desired value via a differential amplifier including a MOS transistor pair, the method comprising:
applying a clock signal to be corrected to a respective gate terminal of the MOS transistor pair of the differential amplifier;
generating a differential analog duty ratio correction signal via integrating a true and complementary clock signal delivered via a source/drain terminal of each MOS transistor of the differential amplifier; and
applying the differential duty ratio correction signal to a correction signal input terminal pair of the differential amplifier, thereby applying the differential duty ratio correction signal to electrically separated substrate terminals of the MOS transistor pair so that in each case substrate voltages, and thus turn-on voltages of the MOS transistors of the transistor pair are conversely influenced.

7. The method according to claim 6, wherein the true and complementary clock signals have a duty ratio of 50%.

8. An amplifier circuit to correct a duty ratio of a differential clock signal to a desired value, the amplifier comprising:
a differential amplifier stage with a MOS transistor pair, of the same conduction type, including:
two gate terminals configured to separately receive complementary components of the clock signal to be corrected;
a source/drain terminal pair configured to deliver complementary components of the clock signal with corrected duty ratio; and
a correction signal input terminal pair configured to receive complementary components of an analog duty ratio correction signal; and
a detector stage connected as an integrator to the correction signal input terminal pair of the differential amplifier stage and configured to generate the analog duty ratio correction signal;
wherein the correction signal input terminal pair comprises electrically separated substrate terminals of the MOS transistor pair so that receipt of the duty ratio correction signal case influences substrate voltages of the MOS transistor pair, thereby conversely influencing a respective turn-on voltage of the MOS transistor pair.

9. The amplifier circuit according to claim 8, wherein the complementary components of the clock signal have a corrected duty ratio of 50%.

10. A method for correcting the duty ratio of a differential clock signal to a desired value via a differential amplifier with a MOS transistor pair of the same type of conduction, the method comprising:
separately applying the complementary components of the clock signal to be corrected to respective gate terminals of the MOS transistor pair;
generating a differential analog duty ratio correction signal via in each case integrating a true and complementary clock signal delivered via a source/drain terminal of each MOS transistor of the differential amplifier; and
applying the differential duty ratio correction signal to a correction signal input terminal pair of the differential amplifier, thereby applying the differential duty ratio correction signal in each case to electrically separated substrate terminals of the MOS transistor pair so that in each case substrate voltages, and thus turn-on voltages of the MOS transistors of the transistor pair are conversely influenced.

11. The method according to claim 10, wherein the true and complementary clock signals have a duty ratio of 50%.
